(19) United States
(12) Patent Application Publication
(10) Pub. No.: US 2016/0002778 A1
(43) Pub. Date: Jan. 7, 2016

(54) SUBSTRATE SUPPORT WITH MORE UNIFORM EDGE PURGE

(71) Applicant: APPLIED MATERIALS, INC., Santa Clara, CA (US)

(72) Inventors: JALLEPALLY RAVI, San Ramon, CA (US); TOMOHARU MATSUSHITA, Narita-shi (JP); ARAVIND MIYAR KAMATH, Santa Clara, CA (US); XIAOXIONG YUAN, San Jose, CA (US); CHENG-HSIUNG MATTHEW TSAI, Cupertino, CA (US); MANJUNATHA KOPPA, Bengaluru (IN)

(21) Appl. No.: 14/476,238

(22) Filed: Sep. 3, 2014

Related U.S. Application Data
(60) Provisional application No. 62/020,893, filed on Jul. 3, 2014.

(51) Int. Cl. C23C 16/458; C23C 16/455; C23C 16/46

(52) U.S. Cl. CPC C23C 16/458; C23C 16/46; C23C 16/455

(57) ABSTRACT

Embodiments of substrate supports are provided herein. In some embodiments, a substrate support may include a first plate for supporting a substrate, the first plate having a plurality of purge gas channels on its backside; a second plate disposed beneath and supporting the first plate; and an edge ring surrounding the first plate and disposed above the second plate, wherein the plurality of purge gas channels extend from a single inlet in a central portion to a plurality of outlets at a periphery of the first plate, and wherein the plurality of purge gas channels have a substantially equal flow conductance.

### CROSS-REFERENCE TO RELATED APPLICATIONS

This application claims benefit of U.S. provisional patent application Ser. No. 62/020,893, filed Jul. 3, 2014, which is herein incorporated by reference.

### FIELD

Embodiments of the present disclosure generally relate to semiconductor processing equipment.

### BACKGROUND

Edge purging is useful in processes performed in metal chemical vapor deposition (MCVD) and metal atomic layer deposition (MALD) chambers to protect the heater surface edge and to prevent the deposition on a backside of a substrate. The inventors have observed that non-uniformity in the injection of edge purge gas will lead to deposition non-uniformity. Thus, the inventors believe that current MCVD and MALD substrate supports are sub-optimal in terms of their edge purging non-uniformity. For example, the inventors have observed that conventional substrate supports can have edge purge non-uniformity in the range of about 17%.

Therefore, the inventors have provided embodiments of substrate supports having more uniform edge purge.

### SUMMARY

Embodiments of substrate supports are provided herein. In some embodiments, a substrate support may include a first plate for supporting a substrate, the first plate having a plurality of purge gas channels on its backside; a second plate disposed beneath and supporting the first plate; and an edge ring surrounding the first plate and disposed above the second plate, wherein the plurality of purge gas channels extend from a single inlet in a central portion to a plurality of outlets at a periphery of the first plate, and wherein the plurality of purge gas channels have a substantially equal flow conductance.

In some embodiments, a process chamber may include a chamber body defining an inner volume; one or more gas inlets to provide a process gas to the inner volume; and a substrate support disposed within the inner volume opposite the one or more gas inlets. The substrate support may include a first plate for supporting a substrate, the first plate having a plurality of purge gas channels on its backside; a second plate disposed beneath and supporting the first plate; and an edge ring surrounding the first plate and disposed above the second plate, wherein the plurality of purge gas channels extend from a single inlet in a central portion to a plurality of outlets at a periphery of the first plate, and wherein the plurality of purge gas channels have a substantially equal flow conductance.

In some embodiments, a substrate support may include a first plate for supporting a substrate, the first plate having a plurality of purge gas channels on its backside; a second plate disposed beneath and supporting the first plate; and an edge ring surrounding the first plate and disposed above the second plate, wherein the plurality of purge gas channels extend from a single inlet in a central portion to a plurality of outlets at a periphery of the first plate, wherein the plurality of purge gas channels have a substantially equal flow conductance, wherein a first cross sectional area of the plurality of purge gas channels in the central portion is greater than a second cross-sectional area of the plurality of purge gas channels at the periphery, and wherein the edge ring and the periphery of the first plate define a choked flow path therebetween.

Other and further embodiments of the present disclosure are described below.

### BRIEF DESCRIPTION OF THE DRAWINGS

Embodiments of the present disclosure, briefly summarized above and discussed in greater detail below, can be understood by reference to the illustrative embodiments of the invention depicted in the appended drawings. It is to be noted, however, that the appended drawings illustrate only typical embodiments of this disclosure and are therefore not to be considered limiting of its scope, for the disclosure may admit to other equally effective embodiments.

FIG. 1 depicts a schematic view of a process chamber suitable for use with a substrate support in accordance with some embodiments of the present disclosure.

FIG. 2 depicts a backside view of a portion of a substrate support in accordance with some embodiments of the present disclosure.

FIG. 3 depicts a isometric, cross-sectional view of a substrate support in accordance with some embodiments of the present disclosure.

FIG. 4 depicts cross-section side view of a substrate support in accordance with some embodiments of the present disclosure.

To facilitate understanding, identical reference numerals have been used, where possible, to designate identical elements that are common to the figures. The figures are not drawn to scale and may be simplified for clarity. It is contemplated that elements and features of one embodiment may be beneficially incorporated in other embodiments without further recitation.

### DETAILED DESCRIPTION

Substrate supports that provide improved purge gas flow are provided herein. Embodiments of the inventive substrate improve the uniformity of purge gas flow around a substrate being processed, thus improving deposition uniformity. While not intended to be limiting of the scope of the disclosure, the inventive substrate support disclosed herein may be particularly advantageous in process chambers configured for chemical vapor deposition (CVD), optionally having radio frequency (RF) capability, for example such as CVD process chambers suitable to process 200, 300, or 450 mm diameter substrates, or the like.

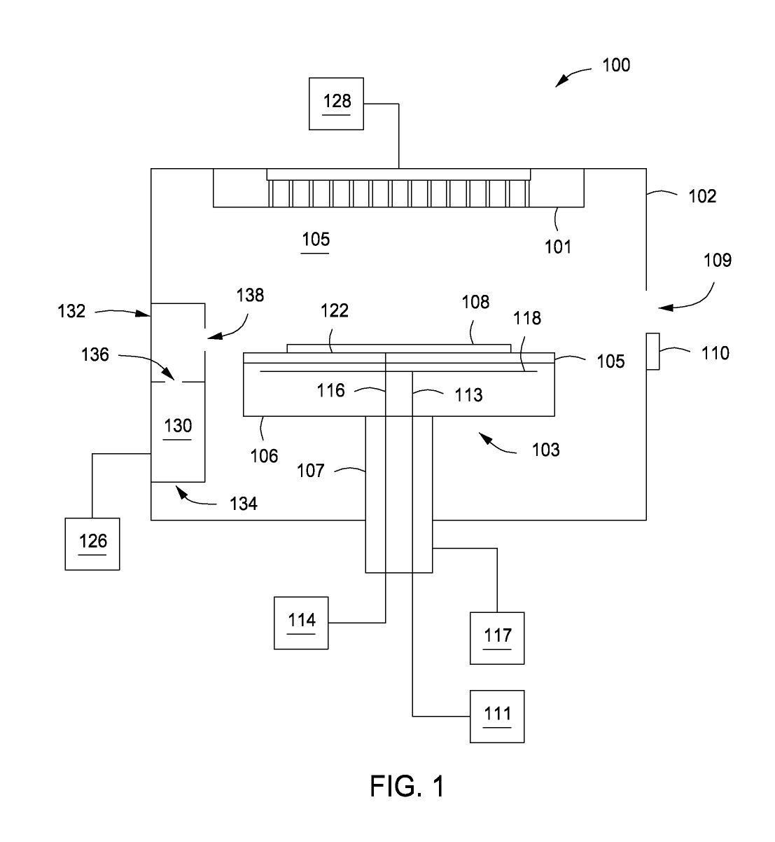

FIG. 1 depicts a process chamber 100 suitable for use with a substrate support having a heater in accordance with some embodiments of the present disclosure. The process chamber 100 may be any process chamber suitable for performing one or more substrate processes, for example, deposition process such as chemical vapor deposition (CVD), physical vapor deposition (PVD), atomic layer deposition (ALD) or the like. In some embodiments, the process chamber is a CVD process chamber. The process chamber may be a standalone process chamber or a part of a cluster tool, such as one of the CENTURA®, PRODUCER®, or ENDURA® cluster tools available from Applied Materials, Inc. of Santa Clara, Calif.

In some embodiments, the process chamber 100 may generally include a chamber body 102, a substrate support 103 for supporting a substrate 104 and one or more gas inlets (e.g., showerhead 101) for providing one or more processes gases to an inner volume 119 of the chamber body 102.

In some embodiments, the chamber body 102 may comprise one or more openings (one opening 109 shown) to allow for the substrate 104 to be provided to, and removed from, the process chamber 100. The opening 109 may be selectively sealed via a slit valve 110, or other mechanism for selectively providing access to the inner volume 119 of the chamber body 102 through the opening 109. In some embodiments, the substrate support 103 may be coupled to a lift mechanism 117 that may control the position of the substrate support 103 between a lower position (as shown) suitable for transferring substrates into and out of the chamber via the opening 109 and a selectable upper position suitable for processing. The process position may be selected to maximize process uniformity for a particular process. When in at least one of the elevated processing positions, the substrate support 103 may be disposed above the opening 109 to provide a symmetrical processing region.

The one or more gas inlets (e.g., showerhead 101) may be coupled to a first gas source 128 for providing one or more process gases for carrying out processes in the process chamber 100. Although a showerhead 101 is shown, additional or alternative gas inlets may be provided such as nozzles or inlets disposed in the ceiling or on the sidewalls of the process chamber 100 or at other locations suitable for providing gases as desired to the process chamber 100, such as the base of the chamber body 102, the periphery of the substrate support 103, or the like.

In some embodiments, the process chamber 100 further includes an exhaust 130 coupled to a pump 126 for removing process gases, purge gases, processing byproducts, and the like from the process chamber 100, for example, via one or more openings 138 fluidly coupling the inner volume 119 of the chamber body 102 with the exhaust 130. In some embodiments, the exhaust 130 may be disposed about the walls of the chamber body 102 and may further be split into an upper exhaust 132 and a lower exhaust 134 with one or more openings 136 disposed between the upper and lower exhaust 132, 134 to control the flow of the process gases, etc., through the exhaust 130 and to the pump 126 (e.g., to provide more azimuthally uniform flow from the processing region of the process chamber above the substrate to the exhaust 130 due to the asymmetric pump configuration).

The substrate support 103 generally comprises a first plate 105 to support a substrate 108 thereon and a second plate (heater plate) 106 configured to support the first plate 105. A substrate support shaft 107 supports the second plate 106. In some embodiments, one or more heating elements 118 may be embedded within or recessed within the second plate 106, thus allowing the second plate 106 to function as a heater. A power source may provide power to the heating element 118 via a conduit 113 disposed within the substrate support shaft 107. In some embodiments, the heating elements 118 may be embedded or recessed within the second plate 106 and may be configured such that multiple heating zones are present across the second plate 106.

A purge gas (e.g., an inert gas, such as argon), is provided by a second gas source 114 to a backside 122 of the substrate 104 via a conduit 116. In some embodiments, the conduit 116 is disposed in a sidewall or within a central opening of the substrate support shaft 107. One or more conduits (described below) are provided to deliver the purge gas proximate the edge of the substrate 104.

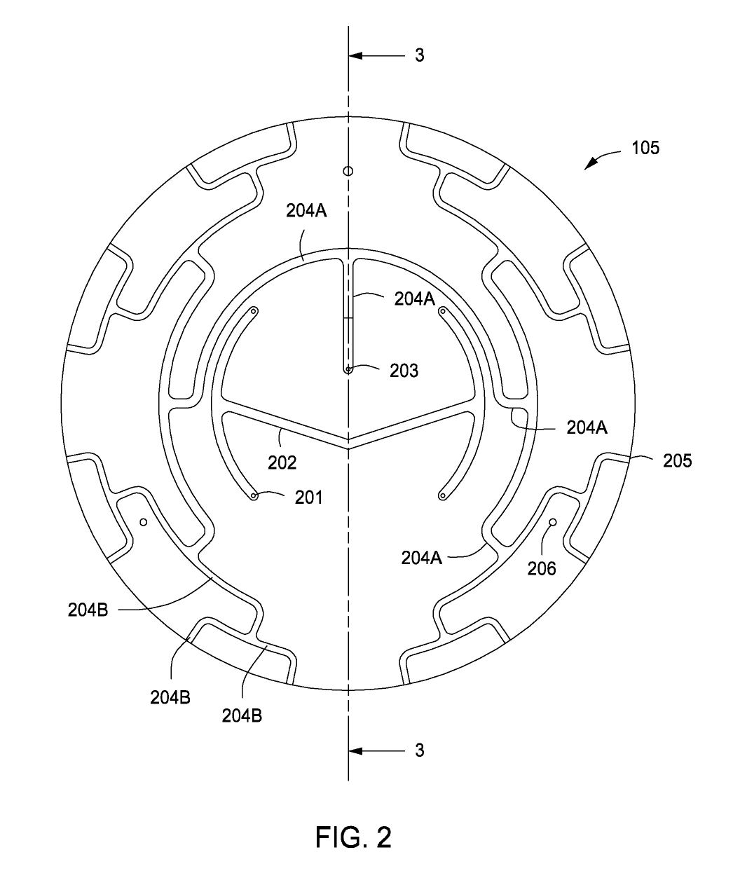

FIG. 2 depicts a backside of the first plate 105 in accordance with some embodiments of the present disclosure. In some embodiments, the first plate 105 may advantageously provide more uniform distribution of the purge gases exiting the periphery of the first plate 105, as compared to conventional substrate supports. As shown in FIG. 2, a plurality of purge gas channels 204A, 204B may spread from a single inlet 203 in a central portion of the first plate 105 to a plurality of outlets 205 at the periphery of the first plate 105. In some embodiments, the purge gas channels 204A, 204B may spread recursively to the plurality of outlets 205 via a plurality of passages.

In some embodiments, the plurality of purge gas channels may have a substantially equal flow conductance. As used herein, the term substantially equivalent, or substantially equal, means within about 10 percent of each other. The terms substantially equivalent or substantially equal, as defined above, may be used to describe other aspects of the disclosure, such as conduit (or channel) length, flow length, cross-sectional area, flow rate, or the like.

In some embodiments, the plurality of purge gas channels may have a substantially equal flow length. In some embodiments, the plurality of purge gas channels may have a substantially equal cross-sectional area along an equivalent position there along (e.g., the cross-sectional area may vary along the length of each passage, but each channel in the plurality of purge gas channels will vary in a substantially equivalent manner). In some embodiments, the plurality of purge gas channels may be symmetrically arranged about the first plate 105. In some embodiments, a first cross-sectional area of each of the plurality of purge gas channels 204A is larger than a second cross-sectional area of each of the plurality of purge gas channels 204B. As a result of this reduced cross-sectional area proximate the periphery of the first plate 105, a choked flow condition is created. Thus, purge gas exits all of the outlets 205 at a substantially equivalent flow rate.

For example, in some embodiments, the single inlet 203 is provided proximate a center of the top plate in order to be aligned with the conduit 116 in the substrate support shaft 107. From there, the plurality of purge gas channels alternatingly extend radially outwardly and along an arc of a radius having a common center with the top plate (and substrate support in general). Each time a purge gas channel extends radially outwardly, it intersects the middle of an arc until the last radially outwardly extending channels exit the first plate 105.

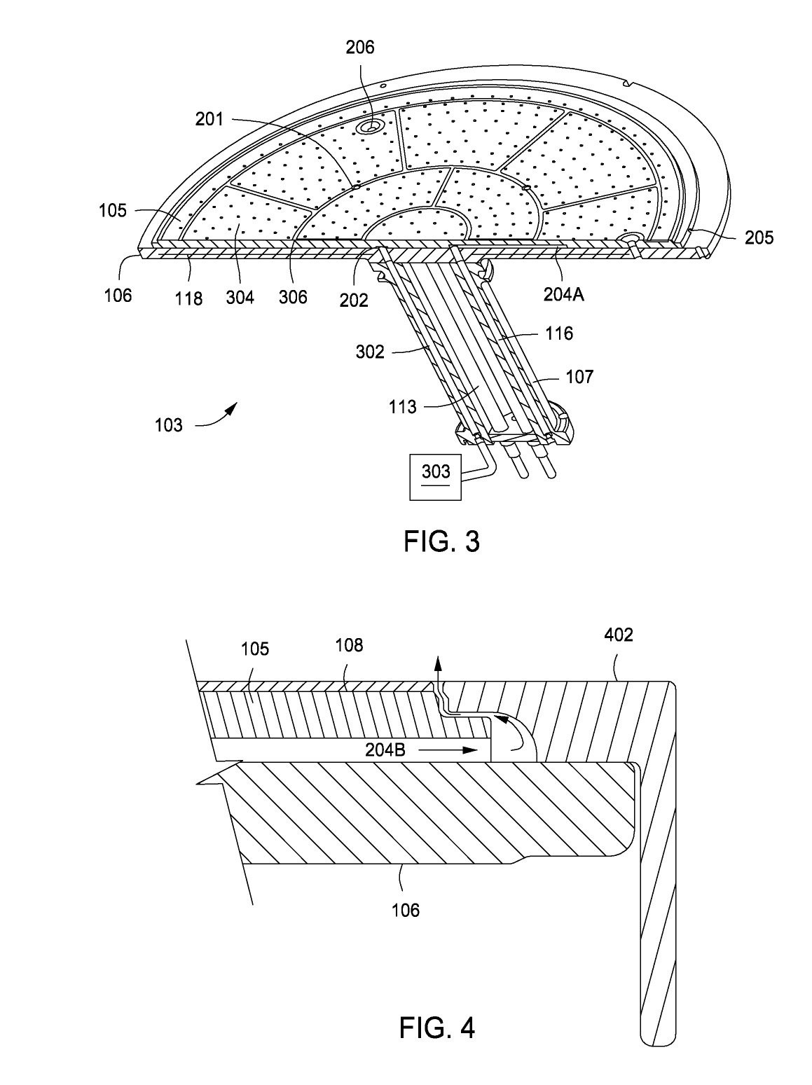

As shown in FIG. 2, vacuum grooves 202 are also machined into the first plate 105. Openings 201 extend through the first plate 105 to fluidly couple the vacuum grooves 202 with a plurality of channels (306 in FIG. 3) on top of the first plate 105. A vacuum chucking supply (not shown) communicates with the vacuum grooves 202 to chuck a substrate 108 when placed atop the first plate 105. The first plate 105 may also include a plurality of lift pin holes 206 to allow lift pins (not shown) to pass therethrough and raise/lower the substrate 108 off/onto the first plate 105.

FIG. 3 depicts a cross-sectional isometric view of the substrate support 103 in accordance with some embodiments of the present disclosure. As seen in FIG. 3, a conduit 302 is coupled to a vacuum chucking supply 303 at one end and opens into the vacuum grooves 202 at an opposite end. The vacuum grooves 202 communicate with a plurality of channels 306 on the top of the first plate 105 via the openings 201 to chuck a substrate 108 placed thereon. In some embodiments, the first plate 105 may include a plurality of contact pads 304 (e.g., sapphire balls) to prevent particle generation on the backside of the substrate 108 when placed thereon.

FIG. 4 depicts a side cross-sectional view of the periphery of the first and second plates 105, 106. In some embodiments, the substrate support 103 may include an edge ring 402 disposed above the second plate 106 and surrounding the first plate 105. The edge ring 402 is spaced apart from the first plate 105 to allow purge gases flowing out of the outlets 205 to flow between the first plate 105 and the edge ring 402 as indicated by the arrows in FIG. 4. In some embodiments, the periphery of the first plate 105 is shaped to correspond with an inner portion of the edge ring 402. In some embodiments, the edge ring 402 and the periphery of the first plate 105 define a choked flow path therebetween. As a result, a more uniform flow of purge gas surrounding the substrate 108 is achieved.

Thus, embodiments of substrate supports that may provide improved purge gas uniformity have been provided herein. The inventive substrate support may improve the uniformity of purge gas flow around a substrate being processed, thus improving deposition uniformity.

While the foregoing is directed to embodiments of the present disclosure, other and further embodiments of the disclosure may be devised without departing from the basic scope thereof.

1. A substrate support, comprising:
a first plate for supporting a substrate, the first plate having a plurality of purge gas channels on its backside;
a second plate disposed beneath and supporting the first plate; and
an edge ring surrounding the first plate and disposed above the second plate, wherein the plurality of purge gas channels extend from a single inlet in a central portion to a plurality of outlets at a periphery of the first plate, and wherein the plurality of purge gas channels have a substantially equal flow conductance.

2. The substrate support of claim 1, wherein the plurality of purge gas channels have a first cross-sectional area in the central portion and a second cross-sectional area at the periphery.

3. The substrate support of claim 2, wherein the second cross-sectional area is less than the first cross-sectional area to create a choked flow condition at the periphery.

4. The substrate support of claim 1, wherein the edge ring is spaced apart from the first plate to create a flow path therebetween.

5. The substrate support of claim 4, wherein the periphery of the first plate is shaped to correspond with an inner portion of the edge ring.

6. The substrate support of claim 5, wherein the edge ring and the periphery of the first plate define a choked flow path therebetween.

7. The substrate support of claim 1, wherein the second plate includes a plurality of heating elements embedded in the second plate to provide a plurality of heating zones.

8. The substrate support of claim 1, wherein the plurality of purge gas channels spread recursively to the plurality of outlets.

9. The substrate support of claim 1, wherein the first plate further comprises:
one or more vacuum grooves on its backside;
a plurality of channels formed on a top of the first plate; and
one or more openings disposed through the first plate to fluidly couple the one or more vacuum grooves to the plurality of channels.

10. A process chamber, comprising:
a chamber body defining an inner volume;
one or more gas inlets to provide a process gas to the inner volume; and
a substrate support disposed within the inner volume opposite the one or more gas inlets, the substrate support comprising:
a first plate for supporting a substrate, the first plate having a plurality of purge gas channels on its backside;
a second plate disposed beneath and supporting the first plate; and
an edge ring surrounding the first plate and disposed above the second plate, wherein the plurality of purge gas channels extend from a single inlet in a central portion to a plurality of outlets at a periphery of the first plate, and wherein the plurality of purge gas channels have a substantially equal flow conductance.

11. The process chamber of claim 10, wherein the plurality of purge gas channels have a first cross-sectional area in the central portion and a second cross-sectional area at the periphery.

12. The process chamber of claim 11, wherein the second cross-sectional area is less than the first cross-sectional area to create a choked flow condition at the periphery.

13. The process chamber of claim 10, wherein the edge ring is spaced apart from the first plate to create a flow path therebetween.

14. The process chamber of claim 13, wherein the periphery of the first plate is shaped to correspond with an inner portion of the edge ring.

15. The process chamber of claim 14, wherein the edge ring and the periphery of the first plate define a choked flow path therebetween.

16. The process chamber of claim 10, wherein the plurality of purge gas channels spread recursively to the plurality of outlets.

17. The process chamber of claim 10, further comprising:
a first gas source to provide the process gas to the one or more gas inlets; and
a second gas source to provide a purge gas to the plurality of purge gas channels.

18. The process chamber of claim 10, wherein the first plate further comprises:
one or more vacuum grooves on its backside;
a plurality of channels formed on a top of the first plate; and
one or more openings disposed through the first plate to fluidly couple the one or more vacuum grooves to the plurality of channels.

19. The process chamber of claim 18, further comprising:
a vacuum chucking supply coupled to the one or more vacuum grooves to chuck a substrate disposed atop the substrate support.

20. A substrate support, comprising:
a first plate for supporting a substrate, the first plate having a plurality of purge gas channels on its backside;
a second plate disposed beneath and supporting the first plate; and
an edge ring surrounding the first plate and disposed above the second plate,
wherein the plurality of purge gas channels extend from a single inlet in a central portion to a plurality of outlets at a periphery of the first plate,
wherein the plurality of purge gas channels have a substantially equal flow conductance,
wherein a first cross sectional area of the plurality of purge gas channels in the central portion is greater than a second cross-sectional area of the plurality of purge gas channels at the periphery, and
wherein the edge ring and the periphery of the first plate define a choked flow path therebetween.
